(19) United States
(12) Patent Application Publication
(10) Pub. No.: US 2016/0172574 A1
(43) Pub. Date: Jun. 16, 2016

(54) PIEZOELECTRIC THIN FILM DEVICE AND METHOD FOR MANUFACTURING THE SAME

(71) Applicant: Murata Manufacturing Co., Ltd., Nagaokakyo-shi (JP)

(72) Inventors: SHINSUKE IKEUCHI, Nagaokakyo-shi (JP); Kansho Yamamoto, Nagaokakyo-shi (JP); Yutaka Kishimoto, Nagaokakyo-shi (JP); Yoshitaka Matsuki, Nagaokakyo-shi (JP); Naoyuki Endo, Nagaokakyo-shi (JP); Toshimaro Yoneda, Nagaokakyo-shi (JP); Yutaka Takeshima, Nagaokakyo-shi (JP)

(21) Appl. No.: 15/053,030

(22) Filed: Feb. 25, 2016

Related U.S. Application Data
(63) Continuation of application No. PCT/JP2014/071888, filed on Aug. 21, 2014.

(30) Foreign Application Priority Data
Sep. 9, 2013 (JP) 2013-186348

(51) Int. Cl. H01L 41/08; H01L 41/29; H01L 41/332

(52) U.S. Cl. CPC H01L 41/0805; H01L 41/332; H01L 41/29

(57) ABSTRACT

A piezoelectric device that includes a piezoelectric film, which is formed by a sputtering method and which has a columnar structure, and electrodes disposed in contact with the piezoelectric film. The piezoelectric film has a composition containing an element which can substitute Nb and has an oxidation number of 2 or more and less than 5 when oxidized in a proportion of 3.3 mol or less relative to 100 mol of potassium sodium niobate represented by a general formula (K₁₋ₓNaₓ)NbO₃, where 0<x<1.

### CROSS REFERENCE TO RELATED APPLICATIONS

The present application is a continuation of International application No. PCT/JP2014/071888, filed Aug. 21, 2014, which claims priority to Japanese Patent Application No. 2013-186348, filed Sep. 9, 2013, the entire contents of each of which are incorporated herein by reference.

### FIELD OF THE INVENTION

The present invention relates to a piezoelectric thin film device that uses a potassium sodium niobate based piezoelectric thin film and a method for manufacturing a piezoelectric thin film device. In particular, the present invention relates to a piezoelectric thin film device in which the piezoelectric thin film is formed by a sputtering method and a method for manufacturing the same.

### BACKGROUND OF THE INVENTION

To date, much focus has been placed on KNN-based materials as lead-free piezoelectric magnetic compositions. The KNN-based materials are piezoelectric materials containing potassium sodium niobate (KNN) as a primary component.

Patent Document 1 below discloses a piezoelectric thin film device including a thin film composed of potassium sodium niobate. In Patent Document 1, the KNN thin film is formed by a sputtering method.

On the other hand, Non Patent Document 1 below discloses a piezoelectric thin film device including a KNN-based piezoelectric thin film formed by a chemical solution deposition (CSD) method. In Non Patent Document 1, 2 percent by mole of Mn is added to 100 percent by mole of KNN.

In addition, Patent Document 2 below discloses a piezoelectric ceramic composition primarily containing KNN having a specific composition. In Patent Document 2, a KNN-based piezoelectric body is formed by firing a raw material powder having a composition in which 0.1 to 10 mol of Mn is contained relative to 100 mol of KNN, where the raw material powder constitutes the piezoelectric magnetic composition. It is mentioned that the firing temperature range at the time of firing can be increased by adding Mn in a proportion of 0.1 to 10 mol.
Patent Document 1: Japanese Unexamined Patent Application Publication No. 2012-19050
Patent Document 2: WO 2006/117952

### Non Patent Document

Non Patent Document 1: Applied Physics Letters 97, 072902, 2010

### SUMMARY OF THE INVENTION

As described in Patent Document 1, in the KNN thin film formed by a sputtering method, the amounts of K and Na may be less than those in the stoichiometric composition. The reason for this is considered to be that crystal defects are generated in the KNN thin film at the time of formation by a sputtering method. Consequently, carriers resulting from crystal defects are generated and there is a problem that current leakage occurs.

Likewise, in the KNN thin film formed by the chemical solution deposition method, as described in Non Patent Document 1, K and Na may be re-vaporized depending on the formation condition, and crystal defects may be generated. Consequently, there is a problem that current leakage also occurs.

Patent Document 2 describes the firing temperature range being increased by addition of the above-described proportion of Mn at the time of firing of not a piezoelectric thin film but a piezoelectric body. However, there is no description in Patent Document 2 that in the case where the KNN thin film is formed by a sputtering method or the chemical solution deposition method, a leakage current is generated because of the above-described crystal defects.

It is an object of the present invention to provide a piezoelectric thin film device which includes a potassium sodium niobate based piezoelectric thin film and in which a leakage current is not generated easily, and a method for manufacturing the same.

A piezoelectric thin film device according to the present invention includes a piezoelectric thin film, which is formed by a sputtering method and which has a columnar structure, and electrodes disposed in contact with the piezoelectric thin film. The piezoelectric thin film has a composition containing an element which can substitute Nb and has an oxidation number of 2 or more and less than 5 when oxidized in a proportion of 3.3 mol or less relative to 100 mol of potassium sodium niobate represented by a general formula (K₁₋ₓNaₓ)NbO₃ (where 0<x<1).

In an aspect of the piezoelectric thin film device according to the present invention, the proportion of the element is 1.0 mol or less relative to 100 mol of the potassium sodium niobate. In this case, the coercive electric field of the KNN-based piezoelectric thin film can be enhanced.

In another aspect of the piezoelectric thin film device according to the present invention, the element is at least one selected from the group consisting of Mn, Cr, Cu, Fe, Pd, Ti, and V.

In another aspect of the piezoelectric thin film device according to the present invention, a substrate is further included. The piezoelectric thin film and the electrodes are stacked on the substrate.

In another aspect of the piezoelectric thin film device according to the present invention, patterning is performed by dry etching.

A method for manufacturing a piezoelectric thin film device, according to the present invention, includes the steps of using a target having a composition containing an element, which can substitute Nb and which has an oxidation number of 2 or more and less than 5 when oxidized, in a proportion of 3.3 mol or less relative to 100 mol of potassium sodium niobate represented by a general formula (K₁₋ₓNaₓ)NbO₃ (where 0<x<1) to form a piezoelectric thin film having the same composition by a sputtering method, and forming electrodes in contact with the piezoelectric thin film before or after the formation of the piezoelectric thin film.

In another aspect of the method for manufacturing a piezoelectric thin film device, according to the present invention, the proportion of the element is 1.0 mol or less relative to 100 mol of the potassium sodium niobate. In this case, the coercive electric field of the piezoelectric thin film can be enhanced.

In another aspect of the method for manufacturing a piezoelectric thin film device, according to the present invention, the element is at least one selected from the group consisting of Mn, Cr, Cu, Fe, Pd, Ti, and V.

In another aspect of the method for manufacturing a piezoelectric thin film device, according to the present invention, the step of performing patterning by dry etching is further included.

According to the piezoelectric thin film device and the method for manufacturing the same of the present invention, the element, which can substitute Nb and which has an oxidation number of 2 or more and less than 5 when oxidized, is contained in a proportion of 3.3 mol or less relative to 100 mol of potassium sodium niobate, so that even when the piezoelectric thin film is formed by a sputtering method, generation of a leakage current can be suppressed effectively. Therefore, a piezoelectric thin film device having good piezoelectricity and the like can be provided.

### BRIEF DESCRIPTION OF THE DRAWINGS

FIG. 1 is a schematic elevational cross-sectional view illustrating the structure of a piezoelectric thin film device according to an embodiment of the present invention.

FIG. 2 is a diagram showing the amount of polarization-electric field hysteresis characteristics of a KNN thin film containing 0.3 percent by mole of Mn added.

FIG. 3 is a diagram showing the amount of polarization-electric field hysteresis characteristics of a KNN thin film not containing Mn.

FIG. 4 is a diagram showing the amount of polarization-electric field hysteresis characteristics of a KNN thin film containing 0.5 percent by mole of Mn added.

FIG. 5 is a diagram showing the amount of polarization-electric field hysteresis characteristics of a KNN thin film containing 1.0 percent by mole of Mn added.

FIG. 6 is a diagram showing the amount of polarization-electric field hysteresis characteristics of a KNN thin film containing 1.7 percent by mole of Mn added.

FIG. 7 is a diagram showing the amount of polarization-electric field hysteresis characteristics of a KNN thin film containing 3.3 percent by mole of Mn added.

FIG. 8 is a diagram showing the amount of polarization-electric field hysteresis characteristics of a KNN thin film containing 5.0 percent by mole of Mn added.

FIG. 9 is a partial cutaway schematic cross-sectional view illustrating a piezoelectric thin film formed by sputtering and having a columnar structure.

FIG. 10 is a partial cutaway schematic cross-sectional view illustrating a piezoelectric thin film formed by a chemical solution deposition method and having a granular structure.

### DETAILED DESCRIPTION OF THE PREFERRED EMBODIMENTS

Specific embodiments according to the present invention will be described below with reference to the drawings, so that the present invention will be made clear.

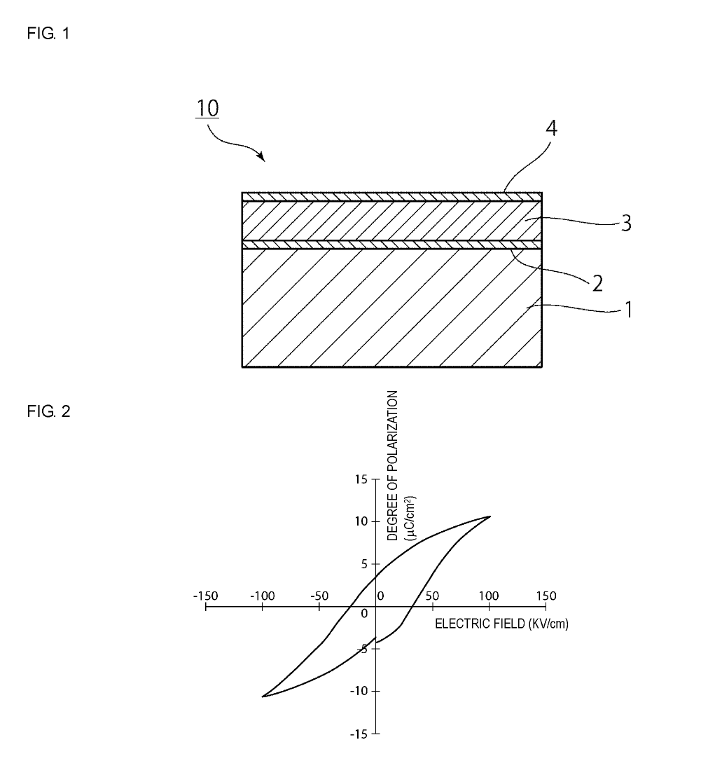

FIG. 1 is a schematic elevational cross-sectional view of a piezoelectric thin film device according to an embodiment of the present invention.

A piezoelectric thin film device 10 includes a substrate 1. A first electrode 2 is stacked on the substrate 1. A piezoelectric thin film 3 composed of a KNN-based piezoelectric material is stacked on the first electrode 2. A second electrode 4 is stacked on the piezoelectric thin film 3.

The piezoelectric thin film 3 is formed by a sputtering method. The piezoelectric thin film 3 has a columnar structure. The piezoelectric thin film 3 has a composition containing Mn in a proportion of 3.3 percent by mole or less relative to 100 percent by mole of potassium sodium niobate represented by the general formula (K₁₋ₓNaₓ)NbO₃ (where 0<x<1). The Nb site of potassium sodium niobate represented by the general formula (K₁₋ₓNaₓ)NbO₃ (where 0<x<1) is substituted with Mn.

In the present embodiment, the Nb site of potassium sodium niobate is substituted with Mn as described above. In the present invention, however, the Nb site may be substituted with another element insofar as Nb can be substituted with the element and the element has an oxidation number of 2 or more and less than 5 when oxidized.

That is, in the piezoelectric thin film device according to the present invention, the piezoelectric thin film has a composition containing the element, which can substitute Nb and which has an oxidation number of 2 or more and less than 5 when oxidized, in a proportion of 3.3 mol or less relative to 100 mol of potassium sodium niobate represented by the general formula (K₁₋ₓNaₓ)NbO₃ (where 0<x<1). Therefore, in the piezoelectric thin film device according to the present invention, leakage-related failure is suppressed.

In the case where the amount of the element, which can substitute Nb and which has an oxidation number of 2 or more and less than 5 when oxidized, is larger than the above-described upper limit, an excess of element not substituted in the crystal precipitates at grain boundaries.

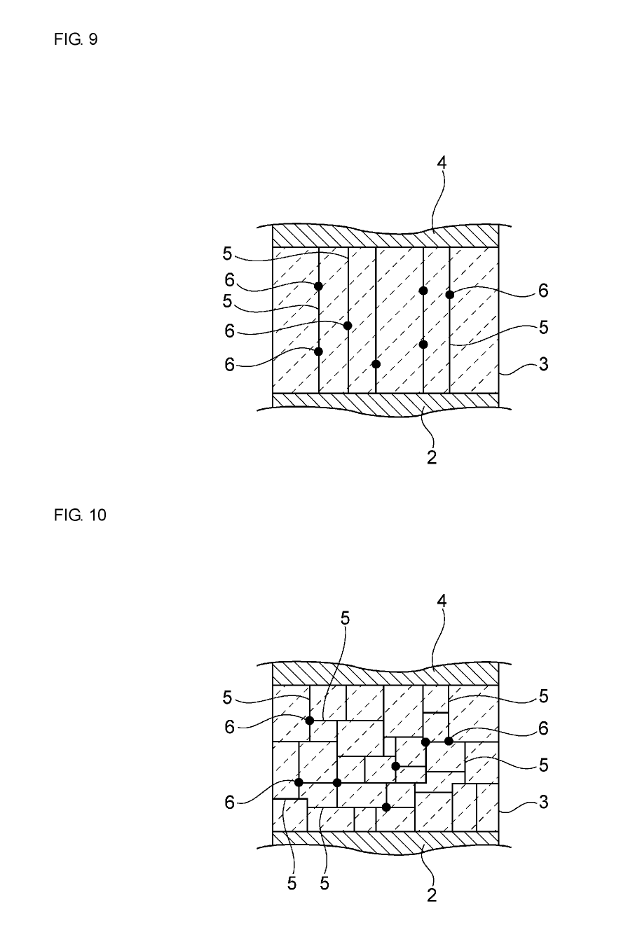

If an excess of element precipitates at grain boundaries, as described above, in particular in the case where the piezoelectric thin film is formed by sputtering and is a thin film having a columnar structure, leakage-related failure occurs. For more details, explanations will be made below with reference to FIG. 9.

FIG. 9 is a partial cutaway schematic cross-sectional view illustrating a piezoelectric thin film formed by sputtering and having a columnar structure. As illustrated in FIG. 9, in the piezoelectric thin film 3 having a columnar structure, a grain boundary 5 extends in the thickness direction and does not cross other grain boundaries 5. In such a structure, an excess precipitation element 6 can be freely present in the grain boundary 5 and, as a result, a leakage current is generated.

On the other hand, in the piezoelectric thin film formed by the chemical solution deposition method and having a granular structure described in Non Patent Document 1 (Applied Physics Letters 97, 072902, 2010), a grain boundary 5 extends in not only the thickness direction but also the directions orthogonal to the thickness direction and has many portions intersecting the other grain boundaries 5, as illustrated in FIG. 10. In such a structure, an excess of precipitation element 6 is stably present in the intersecting portions. That is, in such a structure, an excess of precipitation element 6 cannot be freely present in the grain boundary 5 and, thereby, a leakage current does not flow easily.

As described above, the present inventors found that a leakage current was generated in the case where a piezoelectric thin film having a columnar structure was formed by a sputtering method, and conducted various studies on this problem. As a result, it was found that leakage-related failure was able to be suppressed effectively by employing a composition containing an element, which was able to substitute Nb and which had an oxidation number of 2 or more and less than 5 when oxidized, at the above-described specific proportion, so that the present invention was made. This point will be described later in detail.

Also, in the present invention, the proportion of the element, which can substitute Nb and which has an oxidation number of 2 or more and less than 5 when oxidized, is preferably 1.0 or less relative to 100 mol of potassium sodium niobate. In that case, leakage-related failure can be suppressed more reliably.

A tolerance factor is known as an indicator to show whether a perovskite structure is maintained. The tolerance factor: t is calculated from the atomic radius of each of an A site ion, a B site ion, and an oxygen ion by using Formula (1) described below. It is empirically known that the perovskite structure can be maintained in the case where the tolerance factor satisfies 0.75<t<1.10.

t=(r_{A}+r_{O})/(√2×(r_{B}+r_{O}) Formula (1)

(in Formula (1), r_{A}, r_{B}, and r_{O} represent r_{A}: A site ion radius (ion radius of K or Na), r_{B}: B site ion radius (ion radius of element to be added), and r_{O}: oxygen ion radius, respectively)

Preferably, the element, which can substitute Nb and which has an oxidation number of 2 or more and less than 5 when oxidized, has a B site ion radius satisfying the above-described condition.

Examples of the element, which can substitute Nb and which has an oxidation number of 2 or more and less than 5 when oxidized, include at least one element selected from the group consisting of Mn, Cr, Cu, Fe, Pd, Ti, and V.

In this regard, preferably, the K site and the Na site in potassium sodium niobate represented by the general formula (K₁₋ₓNaₓ)NbO₃ (where 0<x<1) are not substituted with different elements. Alternatively, even when substitution with different elements is performed, it is preferable that Formula (1) described below be satisfied, where an amount a of the K site and the Na site is substituted with an element having an oxidation number of n and an amount b of the Nb site is substituted with an element having an oxidation number of m.

(5−m)×b>(n−1)×a Formula (1)

In the case where the K site and the Na site are not substituted with different elements or are substituted with different elements while Formula (1) described above is satisfied, leakage-related failure can be suppressed more reliably.

In the present embodiment, the piezoelectric thin film 3 has the above-described specific composition and is formed by a sputtering method. Therefore, as described above, leakage-related failure can be suppressed effectively. In this regard, although the thickness of the piezoelectric thin film 3 is not specifically limited, the thickness is usually 5 μm or less because the thin film is formed by a sputtering method.

In the present embodiment, the first electrode 2, the piezoelectric thin film 3, and the second electrode 4 are disposed in this order on the substrate 1. There is no particular limitation regarding what material may be used for the substrate 1. For example, a Si substrate, various types of ceramics and glass, and the like can be used. Also, a semiconductor material may be used as the material for the substrate 1. Further, a single-crystal material may be used.

In addition, the substrate 1 may have a structure in which an insulating film is stacked on a dielectric film, e.g., a SiO₂ film, on the surface of the above-described material.

The first electrode 2 can be formed by using an appropriate metal. As for the material for the first electrode 2, a material stable in even a high-temperature oxygen atmosphere is preferable. Examples of such a material include noble metal materials, e.g., Pt, Au, and Ir, and electrically conductive oxide materials.

The first electrode 2 may be formed from a multilayer metal film in which a plurality of metal layers are laminated. Also, the first electrode 2 can be formed by an appropriate thin film formation method, e.g., a sputtering method or evaporation.

After the first electrode 2 is formed, the above-described piezoelectric thin film 3 is formed by a sputtering method, so that the piezoelectric thin film 3 is formed. Subsequently, the second electrode 4 is formed on the piezoelectric thin film 3. The second electrode 4 can be formed from an appropriate metal material as with the first electrode 2.

An adhesion layer may be disposed so as to bring the above-described first electrode 2 and second electrode 4 into close contact with the substrate 1 and the piezoelectric thin film 3 firmly. That is, it is desirable to dispose the adhesion layer composed of a material having adhesion to the substrate 1 and the piezoelectric thin film 3 higher than the adhesion of the first electrode 2 and the second electrode 4 on the sides, which come into contact with the substrate 1 or the piezoelectric thin film 3, of the first electrode 2 and the second electrode 4. A Ti film can be suitably used as the material constituting such adhesion layer. An adhesion layer made from Ti oxide may be disposed in place of the Ti film. In this regard, the material constituting the adhesion layer may be a material other than Ti and Ti oxide.

Although not illustrated in FIG. 1, a buffer layer may be disposed between the first electrode 2 and the piezoelectric thin film 3. The orientation, the stress, and the surface morphology of the piezoelectric thin film 3 can be adjusted by disposing such a buffer layer. Examples of materials constituting such buffer layer include oxides, e.g., LaNiO₃, having a perovskite structure and a KNN film formed at a low temperature at which crystallization does not occur.

Next, a method for manufacturing the above-described piezoelectric thin film device 10 will be described.

Initially, the substrate 1 composed of the above-described material is prepared. Thereafter, the first electrode 2 is formed on the substrate 1 by the thin film formation method. As described above, formation of the first electrode 2 can be performed by an appropriate thin film formation method, e.g., a sputtering method or evaporation.

Subsequently, the piezoelectric thin film 3 is formed on the first electrode 2 by a sputtering method. As for a sputtering method, an appropriate sputtering method, e.g., an RF magnetron sputtering method, can be used. As described above, a buffer layer may be disposed between the piezoelectric thin film 3 and the first electrode 2 so as to control orientation and stress. In this case, the piezoelectric thin film 3 is formed after the buffer layer is formed.

When forming the piezoelectric thin film 3, a target having a composition in which the above-described specific proportion of Mn is added to KNN may be used. However, methods other than the method that involves using such a target may be used as the method for adding Mn. For example, formation may be performed by using a first target composed of KNN and a second target containing Mn as a primary component at the same time.

The ratio of Na/(K+Na) in the piezoelectric thin film 3 can be changed by changing the atomic ratio of Na/(K+Na) of KNN in each of the above-described targets.

After the piezoelectric thin film 3 is formed, the second electrode 4 is formed in the same manner as the first electrode 2. Post annealing may be performed at a temperature higher than or equal to the heating temperature in formation of the piezoelectric thin film 3 before formation or after formation of the second electrode 4. As a result, the film quality of the piezoelectric thin film 3 can be improved further effectively. Also, the piezoelectric thin film device 10 may be obtained by further performing patterning by dry etching before formation or after formation of the second electrode 4. Consequently, still finer, high-precision processing can be performed.

In the piezoelectric thin film device 10 illustrated in FIG. 1, the piezoelectric thin film 3 held between the first electrode 2 and the second electrode 4 is stacked on the substrate 1. However, the structure of the piezoelectric thin film device according to the present invention is not limited to this. That is, the present invention can be applied to piezoelectric thin film devices having various structures in which the electrodes are disposed so as to come into contact with the piezoelectric thin film having a composition with the above-described characteristics.

In the piezoelectric thin film device 10 according to the present embodiment, the piezoelectric thin film 3 is composed of the KNN thin film having the above-described specific composition. Therefore, failure due to a leakage current can be suppressed, as described above. This will be explained with reference to specific experimental examples.

### Example 1

A SiO₂ film having a thickness of 120 nm was formed on a Si substrate by thermal oxidation. A substrate 1 was prepared in this manner. A Ti film and a Pt film were formed in this order on the substrate 1 by a DC sputtering method, so that a first electrode 2 was formed. The thickness of the Ti film was 5 nm, and the thickness of the Pt film was 100 nm. The Ti film functions as an adhesion layer.

Next, a piezoelectric thin film 3 was formed by the RF magnetron sputtering method. The sputtering condition was as described below.

Substrate heating set temperature: 600° C.

Sputtering pressure: 0.3 Pa

Atmosphere: mixed gas containing Ar/O₂ at a volume ratio of 100/1

Sputtering power density: 2.6 W/cm²

As for the target, a target having a composition in which 0.3 percent by mole of Mn was added to 100 percent by mole of KNN was used.

The atomic ratio of Na/(K+Na) in KNN in the target was specified to be 0.5.

The piezoelectric thin film 3 having a thickness of 1.3 μm was formed as described above.

Then, the Ti film and the Pt film were formed sequentially by an evaporation method, so that the second electrode 4 was formed. The thickness of the Ti film was 5 nm, and the thickness of the Pt film was 100 nm.

The piezoelectric thin film device 10 was obtained in this manner.

### Comparative Example 1

A piezoelectric thin film device was produced similarly to the Example 1 except that Mn was not added to the target and the film thickness of the piezoelectric thin film was 1.2 μm.

### Examples 2 to 5

Piezoelectric thin film devices of Examples 2 to 5 were produced similarly to the Example 1 except that the amount of Mn added in the target was 0.5 percent by mole, 1.0 percent by mole, 1.7 percent by mole, and 3.3 percent by mole, respectively, the ratio of Na/(K+Na) was set as shown in Table 1 below, and the film thickness of the piezoelectric thin film was the value shown in Table 1 below.

### Comparative Example 2

A piezoelectric thin film device was produced similarly to the Example 1 except that the proportion of Mn added to the target was 5.0 percent by mole, the ratio of Na/(K+Na) was 0.46, and the film thickness of the piezoelectric thin film 3 was 1.5 μm.

(Evaluation of Examples 1 to 5 and Comparative Examples 1 and 2)

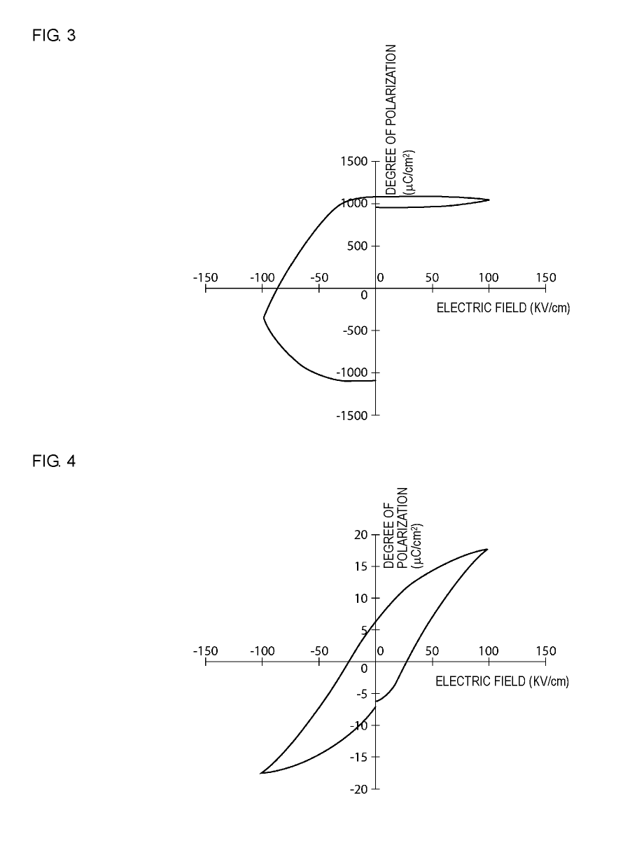

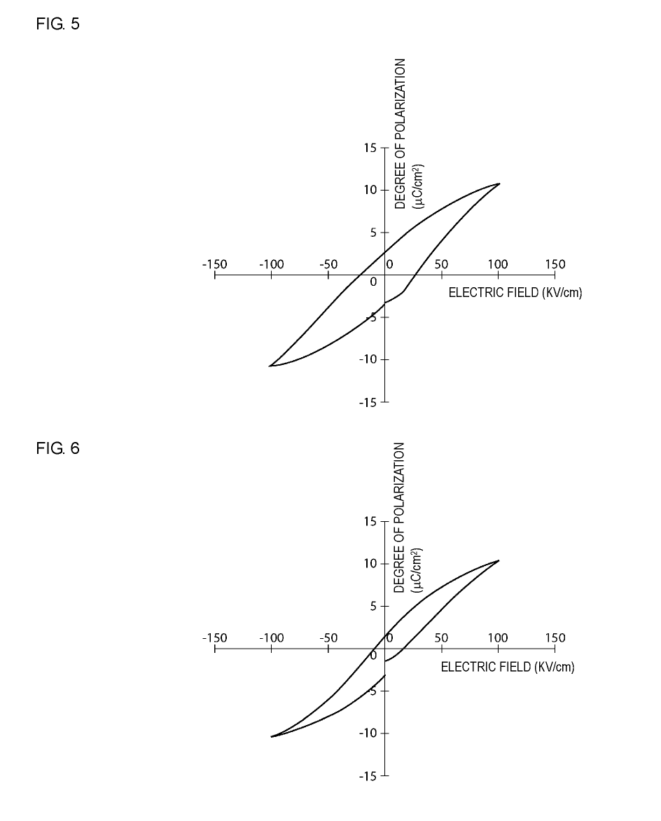

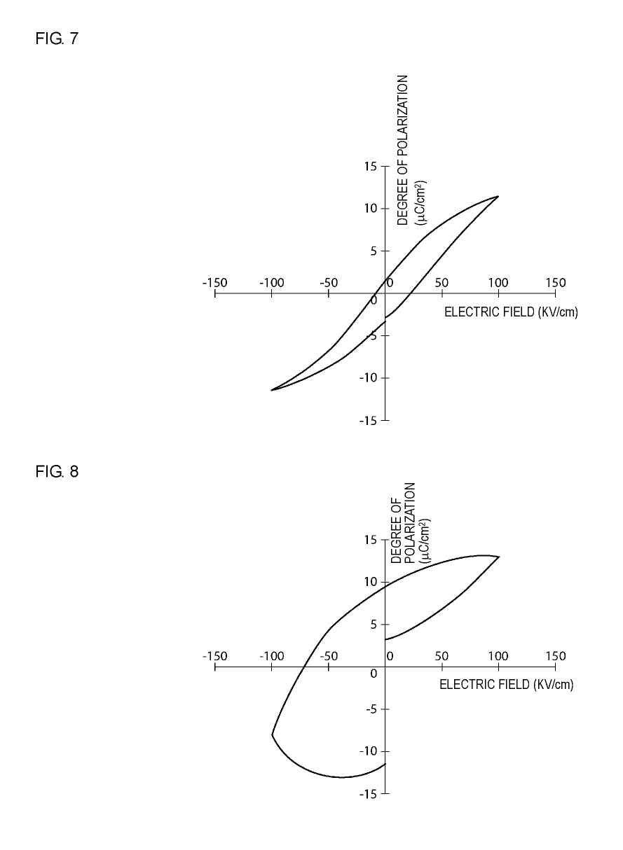

The amount of polarization-electric field hysteresis characteristics of each of the piezoelectric thin film devices obtained as described above were determined. More specifically, a potential difference was given between the first electrode 2 and the second electrode 4 so as to apply an electric field to the piezoelectric thin film 3. The magnitude of this electric field was changed, changes in the polarization characteristics at that time were determined, and the amount of polarization-electric field hysteresis characteristics were determined. The results are shown in FIG. 2 to FIG. 8. FIG. 2 shows the results of Example 1 and FIG. 3 shows the results of Comparative example 1. Also, FIG. 4 to FIG. 7 show the results of Examples 2 to 5 and FIG. 8 shows the results of Comparative example 2.

As is clear from the comparison between FIG. 2 and FIG. 3, in Example 1 in which Mn was added in a proportion of 0.3 percent by mole, the hysteresis characteristics exhibited the shape of a closed loop as compared with that in Comparative example 1 in which Mn was not added. Therefore, it was found that the effect of the leakage current was suppressed effectively.

Likewise, as is clear from FIG. 4 to FIG. 7, the leakage characteristics were improved in Examples 2 to 5.

As is clear from FIG. 8, in Comparative example 2 in which the proportion of addition of Mn was a high proportion of 5.0 percent by mole, the hysteresis characteristics were degraded and the effect of leakage current was large.

Therefore, it was found from the results of Examples 1 to 5 that in the case where the proportion of addition of Mn was 3.3 percent by mole or less, the leakage current related failure was able to be suppressed effectively.

Meanwhile, the coercive electric fields of the piezoelectric thin film devices in Examples 1 to 5 were determined and the results shown in Table 1 below were obtained.

As is clear from Table 1, according to Examples 1 to 3, the coercive electric fields were increased as compared with Examples 4 and 5. Therefore, it was found that a piezoelectric thin film device using a KNN thin film exhibiting an enhanced coercive electric field was able to be provided by specifying the proportion of addition of Mn to be preferably 1.0 percent by mole or less.

TABLE 1

| | Amount of | | | | Negative-side | Positive-side |
|---|---|---|---|---|---|---|
| | addition of Mn | | Film thickness | | coercive electric | coercive electric |
| | (percent by mole) | Na/(K + Na) | (μm) | Leakage | field (kV/cm) | field (kV/cm) |
| Comparative | 0.0 | 0.50 | 1.2 | X | unmeasurable | unmeasurable |
| example 1 | | | | | | |
| Example 1 | 0.3 | 0.50 | 1.3 | ◯ | −22.8 | 31.6 |
| Example 2 | 0.5 | 0.75 | 2.3 | ◯ | −22.7 | 29.3 |
| Example 3 | 1.0 | 0.50 | 0.9 | ◯ | −22.0 | 26.3 |
| Example 4 | 1.7 | 0.49 | 1.2 | ◯ | −10.0 | 15.4 |
| Example 5 | 3.3 | 0.47 | 1.2 | ◯ | −14.4 | 19.8 |
| Comparative | 5.0 | 0.46 | 1.5 | X | unmeasurable | unmeasurable |
| example 2 | | | | | | |

The evaluation symbols in Table 1 represent the following.

Evaluation symbols of leakage: The symbol x indicates that the hysteresis characteristics exhibit a shape much different from a closed loop, and the symbol ◯ indicates that the hysteresis characteristics exhibit the shape of a closed loop or the shape close to a closed loop.

### REFERENCE SIGNS LIST

1 substrate
2 first electrode
3 piezoelectric thin film
4 second electrode
5 grain boundary
6 precipitation element
10 piezoelectric thin film device

1. A piezoelectric device comprising:
a piezoelectric film having a columnar structure; and
electrodes disposed in contact with the piezoelectric film,
wherein the piezoelectric film has a composition containing an element which can substitute Nb and has an oxidation number of 2 or more and less than 5 when oxidized, the element being in a proportion of 3.3 mol or less relative to 100 mol of potassium sodium niobate represented by a general formula (K₁₋ₓNaₓ)NbO₃, where 0<x<1.

2. The piezoelectric device according to claim 1, wherein the piezoelectric film is a sputtered piezoelectric film.

3. The piezoelectric device according to claim 1, wherein the proportion of the element is 1.0 mol or less relative to 100 mol of the potassium sodium niobate.

4. The piezoelectric device according to claim 1, wherein the element is at least one selected from the group consisting of Mn, Cr, Cu, Fe, Pd, Ti, and V.

5. The piezoelectric device according to claim 2, wherein the element is at least one selected from the group consisting of Mn, Cr, Cu, Fe, Pd, Ti, and V.

6. The piezoelectric device according to claim 3, wherein the element is at least one selected from the group consisting of Mn, Cr, Cu, Fe, Pd, Ti, and V.

7. The piezoelectric device according to claim 1, further comprising a substrate, wherein the piezoelectric film and the electrodes are stacked on the substrate.

8. The piezoelectric device according to claim 1, wherein the piezoelectric film has a thickness of 5 μm or less.

9. A method for manufacturing a piezoelectric device, the method comprising:
using a target having a composition containing an element which can substitute Nb and has an oxidation number of 2 or more and less than 5 when oxidized in a proportion of 3.3 mol or less relative to 100 mol of potassium sodium niobate represented by a general formula (K₁₋ₓNaₓ)NbO₃, where 0<x<1, to form a piezoelectric film by sputtering; and
forming electrodes in contact with the piezoelectric film.

10. The method for manufacturing a piezoelectric device according to claim 9, wherein the electrodes are formed before the piezoelectric film is formed.

11. The method for manufacturing a piezoelectric device according to claim 9, wherein the electrodes are formed after the piezoelectric film is formed.

12. The method for manufacturing a piezoelectric device according to claim 9, wherein the proportion of the element is 1.0 mol or less relative to 100 mol of the potassium sodium niobate.

13. The method for manufacturing a piezoelectric device according to claim 9, wherein the element is at least one selected from the group consisting of Mn, Cr, Cu, Fe, Pd, Ti, and V.

14. The method for manufacturing a piezoelectric device according to claim 12, wherein the element is at least one selected from the group consisting of Mn, Cr, Cu, Fe, Pd, Ti, and V.

15. The method for manufacturing a piezoelectric device according to claim 9, further comprising patterning the piezoelectric device by dry etching.
